(19) United States
(12) Patent Application Publication
(10) Pub. No.: US 2026/0056481 A1
(43) Pub. Date: Feb. 26, 2026

(54) SUBSTRATE PROCESSING SYSTEM AND SUBSTRATE PROCESSING METHOD USING SAME

(71) Applicant: Samsung Electronics Co., Ltd., Suwon-si (KR)

(72) Inventors: Kiyoon JANG, Suwon-si (KR); Heeyoung GO, Suwon-si (KR); Hyun Chol CHOI, Suwon-si (KR)

(21) Appl. No.: 19/047,678

(22) Filed: Feb. 7, 2025

(30) Foreign Application Priority Data
Aug. 20, 2024 (KR) 10-2024-0111051

(51) Int. Cl. G03F 7/00; G03F 7/38; G03F 7/40

(52) U.S. Cl. CPC G03F 7/70925; G03F 7/38; G03F 7/40; G03F 7/70525; G03F 7/70608; G03F 7/7075

(57) ABSTRACT

Provided is a substrate processing method, including performing a first surface treatment on a first surface of a substrate, subsequently applying a photoresist film on a second surface of the substrate, subsequently performing a second surface treatment on the first surface of the substrate, after performing the second surface treatment, radiating light towards the photoresist film to form a photoresist pattern area, and forming a photoresist pattern by removing from the photoresist film an area of the photoresist film other than the photoresist pattern area to form a photoresist pattern.

### CROSS-REFERENCE TO RELATED APPLICATION

This application claims priority to Korean Patent Application No. 10-2024-0111051, filed in the Korean Intellectual Property Office on Aug. 20, 2024, the entire contents of which are hereby incorporated by reference.

### BACKGROUND

### Field

The present disclosure relates to a substrate processing system and a substrate processing method using the same.

### Description of Related Art

In general, semiconductor devices may be manufactured by repeating the process of sequentially stacking thin films to form a desired (and/or alternatively predetermined) circuit pattern on a silicon wafer. In order to form and stack the thin films on the silicon wafer, a number of unit processes such as a deposition process, a photolithography process, an etching process, etc. may be repeatedly performed.

Among these unit processes, the photolithography process is a process for forming a pattern on the wafer, and may include a coating process, an exposure process, a developing process, etc. The uppermost layer of the wafer may be etched with the pattern formed on the wafer by the development process such that the element may be formed according to the pattern.

However, the interior of process equipment may be contaminated due to defects in particles on the substrate, etc. during the manufacturing process of the semiconductor devices, resulting in a decrease in productivity. Further, this can lead into a problem in which the temperature does not rise sufficiently when heating the substrate or the substrate is heated unevenly across the positions.

### SUMMARY

To address one or more problems (e.g., the problems described above and/or other problems not explicitly described herein), the present disclosure provides a substrate processing system and a substrate processing method using the same.

The problems addressed by the present disclosure are not limited to those described above, and other problems not mentioned can be clearly understood by those skilled in the art from the description of the disclosure below.

According to some example embodiments of the present disclosure, a substrate processing method may include performing a first surface treatment on a first surface of a substrate, subsequently applying a photoresist film on a second surface of the substrate, subsequently performing a second surface treatment on the first surface of the substrate, after performing the second surface treatment, radiating light towards the photoresist film to form a photoresist pattern area, and forming a photoresist pattern by removing from the photoresist film an area of the photoresist film other than the photoresist pattern area to form a photoresist pattern.

According to some example embodiments of the present disclosure, a substrate processing method may include performing, by a surface treatment chamber, a first surface treatment on a first surface of a substrate, subsequently applying, by a coating station, a photoresist film on a second surface of the substrate, subsequently performing, by the surface treatment chamber, a second surface treatment on the first surface of the substrate, transferring by a transport, the substrate applied with a photoresist film to an exposure station in which a photoresist pattern is formed on the substrate by light radiated toward the photoresist film and transferring the substrate comprising a photoresist pattern area that is formed by light radiated toward the photoresist film, wherein the exposure station is part of a system in which each step to be performed, and forming, by a developing chamber, a photoresist pattern by removing from the photoresist film an area of the photoresist film other than the photoresist pattern area to form a photoresist pattern.

According to some example embodiments of the present disclosure, a substrate processing system may include a surface treatment chamber for performing a surface treatment on a first surface of a substrate, a coating station for applying a photoresist film onto a second surface of the substrate, an exposure station for radiating light towards the photoresist film to form a photoresist pattern area on the photoresist film, and a developing for removing from the photoresist film an area of the photoresist film other than the photoresist pattern area to form a photoresist pattern, and the surface treatment chamber for performing a first surface treatment on the first surface of the substrate, before the coating station applies the photoresist film onto the second surface of the substrate, the surface treatment chamber performs a second surface treatment on the first surface of the substrate, before the exposure station radiates the light towards the photoresist film, and a controller configured to cause each step to be performed.

According to some example embodiments of the present disclosure, the substrate processing system may include a surface treatment chamber that for performing a surface treatment on a first surface of a substrate, a coating station that for applying a photoresist film onto a second surface of the substrate, a transport for transporting the substrate applied with the photoresist film to and from an exposure station for forming a photoresist pattern area on the substrate by light radiated toward the photoresist film, and a developing chamber for removing from the photoresist film an area of the photoresist film other than the photoresist pattern area to form a photoresist pattern, in which the surface treatment chamber may perform a first surface treatment on the first surface of the substrate before the coating station applies the photoresist film onto the second surface of the substrate, performs a second surface treatment on the first surface of the substrate before transferring the substrate to radiate the light towards the photoresist film, and a controller configured to cause each step to be performed.

According to some example embodiments of the present disclosure, when heating a substrate using a bake unit, the problem of the substrate being heated unevenly depending on positions on the substrate due to contamination of the substrate surface can be prevented.

According to some example embodiments of the present disclosure, contamination of the coating unit and the bake unit that may occur due to particle contamination, etc. can be reduced, and cross-contamination of the other substrates that may occur due to the contamination of the coating unit and the bake unit can also be reduced.

Various and beneficial advantages and effects of the present disclosure are not limited to those described above, and can be more easily understood in the course of describing specific aspects of the present disclosure.

### BRIEF DESCRIPTION OF THE DRAWINGS

The above and other objects, features and advantages of the present disclosure will become more apparent to those of ordinary skill in the art by describing in detail exemplary aspects thereof with reference to the accompanying drawings, in which:

FIG. 1A is an example diagram of a substrate processing system according to some example embodiments;

FIG. 1B is a plan view illustrating a configuration of one side of the substrate processing system of FIG. 1A;

FIG. 2 is a block diagram schematically illustrating a detailed configuration of the substrate processing system;

FIG. 3A is a flowchart of a substrate processing method;

FIG. 3B is a flowchart of the operation S320 in FIG. 3A in detail;

FIG. 4 is a diagram illustrating a detailed structure of a bake unit;

FIG. 5 is a flowchart of a substrate processing method according to another aspect;

FIGS. 6A and 6B are diagrams illustrating an example in which surface treatment on a substrate is performed by a surface treatment unit;

FIG. 7A is a block diagram of an arrangement between units in a track device;

FIG. 7B is a block diagram illustrating an arrangement between units in a track device according to another aspect;

FIGS. 8A to 8C are diagrams illustrating examples of a brush according to various aspects; and

FIG. 9 is a diagram provided to compare the levels of particle contamination on the substrate between when the surface treatment of the first surface treatment unit of FIGS. 7A and 7B is performed and when there is no surface treatment.

### DETAILED DESCRIPTION

The present disclosure now will be described more fully hereinafter with reference to the accompanying drawings, in which various embodiments are shown. The invention may, however, be embodied in many different forms and should not be construed as limited to the example embodiments set forth herein. These example embodiments are just that—examples—and many implementations and variations are possible that do not require the details provided herein. It should also be emphasized that the disclosure provides details of alternative examples, but such listing of alternatives is not exhaustive.

Throughout the specification, when a component is described as “including” a particular element or group of elements, it is to be understood that the component is formed of only the element or the group of elements, or the element or group of elements may be combined with additional elements to form the component, unless the context indicates otherwise.

Items described in the singular herein may be provided in plural, as can be seen, for example, in the drawings. Thus, the description of a single item that is provided in plural should be understood to be applicable to the remaining plurality of items unless context indicates otherwise.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

Spatially relative terms, such as “below,” “lower,” “above,” “upper,” “bottom,” and the like, may be used herein for ease of description to describe positional relationships, such as illustrated in the figures, for example. It will be understood that the spatially relative terms encompass different orientations of the device in addition to the orientation depicted in the figures. The terms “subsequently” and “after” as used herein, do not mean that a step is performed immediately following a previous step. Intermediate steps may be included therebetween.

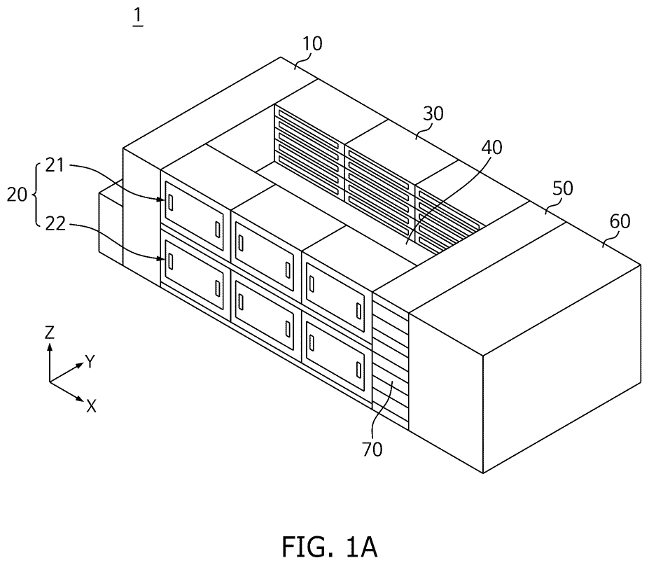

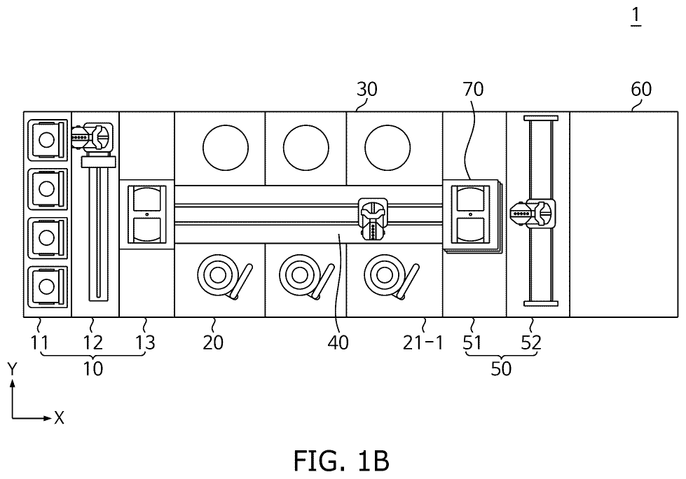

FIG. 1A is an example diagram of a substrate processing system 1 according to some example embodiments. FIG. 1B is a plan view illustrating a configuration of one side of the substrate processing system 1 of FIG. 1A. The substrate processing system 1 may be a system for performing a lithography process of forming a circuit or pattern on a semiconductor substrate using light.

Referring to FIGS. 1A and 1B, the substrate processing system 1 may include an index unit 10, a spin unit 20, a bake unit 30, a transfer unit 40, a transport 50, an exposure unit 60, and a surface treatment unit 70. The spin unit 20, the bake unit 30, and the transfer unit 40 may be referred to as a process unit.

Each of the “units” herein is a station or chamber for performing the associated processes and may include appropriate equipment, such as heaters, for performing these processes.

The index unit 10 may include a plurality of load ports 11, an index robot 12, and a first buffer station 13. The index unit 10 may transfer a substrate input from outside the substrate processing system 1 to the spin unit 20, etc.

The load port 11 may have a mounting table on which a cassette holding the substrate received therein is placed. The load port 11 may include a plurality of mounting tables, and the plurality of mounting tables may be arranged in a row in a y-direction Y. Although FIG. 1B illustrates that the load port 11 includes four mounting tables, aspects are not limited thereto. The number of mounting tables included in the load port 11 may vary depending on aspects. The index robot 12 may transfer the substrate between the load port 11 and the first buffer station 13. The index robot 12 may include a frame, a transfer robot, and a guide rail. The frame may be generally provided in the shape of a hollow cuboid, and may be disposed between the load port 11 and the first buffer station 13. The transfer robot and the guide rail may be disposed inside the frame. The transfer robot may be capable of four-axis driving so as to be moved and rotated in x-direction X, y-direction Y, and z-direction Z.

The first buffer station 13 may be provided in the shape of a hollow cuboid that can temporarily store a plurality of substrates. The first buffer station 13 may be disposed between the index robot 12 and the process unit including the spin unit 20, the bake unit 30, and the transfer unit 40.

The spin unit 20 may include a coating unit 21 that forms a photoresist film on the substrate by coating the photoresist on the substrate before the exposure process, and a developing unit 22 that forms a photoresist pattern from the photoresist pattern area by developing the substrate after the exposure process. The coating unit 21 and the developing unit 22 may be disposed to be partitioned into different layers. For example, the coating unit 21 may be disposed above the developing unit 22. As another example, the coating unit 21 may be disposed below the developing unit 22.

The coating unit 21 may perform a process of coating a photosensitive solution such as a photoresist on the substrate. In some example embodiments, the coating unit 21 may apply the photoresist film on the substrate. For example, the photoresist film may include a positive developing agent that dissolves away an area exposed to light irradiation, and a negative developing agent that dissolves away an area not exposed to light irradiation. The photoresist film may be deposited on the substrate and may be used as a resist for the lithographic process.

The photoresist film coated on the substrate may include a photosensitive material that reacts to extreme ultraviolet (EUV) rays. The photosensitive material may include a sensitive metal, a metal oxide, etc. For example, the photosensitive material may include tin (Sn), hafnium (Hf), bismuth (Bi), indium (In), antimony (Sb), iodine (I), and/or germanium (Ge).

The coating unit 21 may include a plurality of coating chambers 21-1. The coating chambers 21-1 of the coating unit 21 may be continuously disposed in the x-direction X, and may be stacked in the z-direction Z. The plurality of coating chambers 21-1 may all have the same configuration. Different types of coating materials (e.g., HexaMethylDiSilazane (HMDS), photoresist, etc.) may be used in each of the coating chambers 21-1.

FIG. 1B illustrates that three coating chambers 21-1 are disposed in the x-direction X, but aspects are not limited thereto. The number of coating chambers 21-1 disposed along the x-direction X and/or the z-direction Z may be variously modified depending on aspects.

The developing unit 22 may perform a developing process of removing a portion of the photoresist by supplying a developer on the substrate to obtain a pattern. The developing unit 22 may remove an area of the photoresist on the substrate exposed to light irradiation. Depending on the type of photoresist that is selectively used, only an area of the photoresist not exposed to light irradiation may be removed.

In some example embodiments, the developing unit 22 may remove an area of the photoresist (e.g., unnecessary area) other than the photoresist pattern area from the photoresist film through the developing process, thereby forming a photoresist pattern. The developing process may include a dry developing process of removing the area other than photoresist pattern area using a developing gas and/or a wet developing process of removing the area other than the photoresist pattern area using a developer.

The developing unit 22 may develop the photoresist pattern area to form a photoresist pattern from the photoresist film on the substrate. For example, the developing process may include a positive phenomenon and a negative phenomenon. In the positive phenomenon, the area exposed to light irradiation dissolves away to form a photoresist pattern. In the negative phenomenon, the area not exposed to light irradiation dissolves away to form a photoresist pattern.

The developing unit 22 may include a plurality of developing chambers. The developing chambers of the developing unit 22 may be continuously disposed in the x-direction X and stacked in the z-direction Z. The number of developing chambers disposed along the x-direction X and/or z-direction Z may be variously modified depending on various aspects. The plurality of developing chambers may all have the same configuration. Different types of developers may be used in each of the developing units 22.

The bake unit 30 may perform a heat treatment process of heating or cooling the substrate. The bake unit 30 may heat the photoresist film or the photoresist pattern formed on the substrate through a bake process in the heating chamber.

The bake unit 30 may perform a pre-bake process of heating the substrate at a desired (and/or alternatively predetermined) temperature before coating the photoresist to remove organic matter or moisture from the substrate surface, a soft bake process performed after coating the photoresist film on the substrate, a post-bake process of heating the substrate before the developing process is performed, a hard bake process of heating the substrate (or photoresist pattern) after the developing process is performed, and a cooling process of cooling the heated substrate after each bake process.

The bake unit 30 may include a plurality of baking chambers. The baking chambers of the bake unit 30 may be continuously disposed in the x-direction X and stacked in the z-direction Z. FIG. 1B illustrates that three baking chambers are disposed in the x-direction X and six baking chambers are stacked in the z-direction Z, but aspects are not limited thereto. The number of baking chambers disposed along the x-direction X and/or z-direction Z may be variously modified depending on various aspects.

Each baking chamber may have a corresponding cooling plate and/or a corresponding heating plate. The cooling plate may be provided with a cooling unit such as a coolant or a thermoelectric element. The heating plate may be provided with a heating unit such as a heating wire or a thermoelectric element. Some of the plurality of baking chambers may include only the cooling plate, and the other baking chambers may include only the heating plate. One baking chamber may include both the cooling plate and the heating plate.

The bake unit 30 may heat, at a first temperature, the photoresist film formed through the coating process. Accordingly, the bake unit 30 may remove the organic solvent in the photoresist film. The bake unit 30 may further increase the contrast of the etching selectivity by heating the photoresist film. For example, the first temperature may be within a range of 90 to 110 degrees.

The bake unit 30 may heat, at a second temperature, the photoresist film that includes the photoresist pattern area formed as a result of performing the exposure process. Accordingly, the bake unit 30 may diffuse the acid in the area of the photoresist pattern area exposed to light irradiation to improve the uneven pattern. For example, the second temperature may be within a range of 110 to 120 degrees.

The bake unit 30 may heat, at a third temperature, the photoresist pattern formed as a result of performing the developing process. Accordingly, the bake unit 30 may improve the adhesion between the substrate and the photoresist pattern. The bake unit 30 may improve durability and etch resistance of the photoresist pattern. The bake unit 30 may remove a residual solvent in the photoresist pattern. For example, the third temperature may be within a range of 110 to 130 degrees.

The bake unit 30 may inject reactive gas into the heating chamber during the bake process. For example, the reactive gas may include one or more of air, water (H₂O), hydrogen peroxide (H₂O₂), carbon dioxide (CO₂), carbon monoxide (CO), oxygen (O₂), ozone (O₃), methane (CH₄), methanol (CH₃OH), nitrogen (N₂), hydrogen (H₂), ammonia (NH₃), nitrogen dioxide (N₂O), nitrogen monoxide (NO), argon (Ar), and helium (He), etc.

The transfer unit 40 may be disposed parallel to the first buffer station 13 and a second buffer station 51 in the x-direction X. A robot and a guide rail may be positioned in the transfer unit 40. The transfer unit 40 may have a rectangular shape. The robot may transfer the substrate between the first buffer station 13, the coating unit 21, the developing unit 22, the bake unit 30, and the transport 50 (e.g., the second buffer station 51). The guide rail may extend in the x-direction X. The guide rail may guide the robot to move linearly in the x-direction X.

The spin unit 20, the transfer unit 40, and the bake unit 30 may be disposed along the y-direction Y. The coating unit 21 and the developing unit 22 may be positioned to face the bake unit 30 with the transfer unit 40 interposed therebetween.

The transport 50 may transfer the substrate between the exposure unit 60 and the process unit including the spin unit 20, the bake unit 30, and the transfer unit 40. For example, the transport 50 may deliver the substrate coated with the photoresist film to outside of the substrate processing system 1 (e.g., to the exposure unit 60), and receive the substrate with the photoresist pattern area formed upon light irradiation onto the photoresist film from outside of the substrate processing system 1 (e.g., from the exposure unit 60). The transport 50 may include the second buffer station 51 and a transport robot 52.

The second buffer station 51 may temporarily store the substrate. The second buffer station 51 may include a plurality of chambers accommodating the substrates (hereinafter corresponding to a “first buffer chamber” and a “second buffer chamber”) therein. The first buffer chamber may temporarily store the substrate transferred from the process unit (e.g., the coating unit 21) to the exposure unit 60. The second buffer chamber may temporarily store the substrate transferred from the exposure unit 60 to the process unit (e.g., the bake unit 30).

The formation in which the first buffer chamber and the second buffer chamber are disposed in the second buffer station 51 may be modified depending on aspects. For example, the first buffer chamber and the second buffer chamber may be stacked in the z-direction Z in the second buffer station 51.

As another example, the first buffer chamber and the second buffer chamber may be disposed side by side in the x-direction X or the y-direction Y. In this case, a plurality of first buffer chambers may be stacked to form a first buffer tower, and a plurality of second buffer chambers may be stacked to form a second buffer tower. The first buffer tower and the second buffer tower may be arranged side by side in the x-direction X or y-direction Y.

The second buffer station 51 may include a chamber in which the substrate is not accommodated. The surface treatment unit 70 may be disposed in the second buffer station 51. This will be discussed in detail below.

The transport robot 52 may transfer the substrate between the second buffer station 51 and the exposure unit 60.

The exposure unit 60 may radiate light towards(e.g. onto) the substrate formed with the photoresist film using a stepper to form a circuit pattern on the substrate. The exposure unit 60 may radiate light onto the photoresist film formed on the substrate to form a photoresist area for forming a photoresist pattern. The exposure unit 60 may align a mask on the substrate and radiate light onto the mask to form a photoresist pattern area.

The exposure unit 60 may align a mask having a photoresist pattern area on a photoresist film formed on the substrate. The exposure unit 60 may expose, to extreme ultraviolet rays, the photoresist film on which the mask is aligned. The extreme ultraviolet rays may be irradiated onto the photoresist film to cause changes in chemical composition and cross-linking of the photoresist film. The extreme ultraviolet rays may generate contrast with etch selectivity on the photoresist film.

The surface treatment unit 70 may perform surface treatment on one or both surfaces of the substrate. For example, the surface treatment may include a cleaning process and/or a polishing process to physically/chemically remove contaminants (e.g., organic matter, oxide, particles, etc.) on surface for one or both surfaces of the substrate.

The surface treatment performed on one or both surfaces of the substrate by the surface treatment unit 70 may include a process of non-selectively etching the photoresist film or photoresist pattern or an edge bead removal (EBR) process to uniformly remove a film having various levels of oxidation or cross-linking on the back surface or edge area of the substrate.

The surface treatment performed on one or both surfaces of the substrate by the surface treatment unit 70 may include a process of physically removing contamination on the surface of the substrate using one or more brushes.

The surface treatment performed on one or both surfaces of the substrate by the surface treatment unit 70 may include a process of cleaning the substrate through a cleaning gas. For example, the cleaning gas may include one or more gases selected from hydrogen bromide (HBr), hydrogen chloride (HCl), boron trichloride (BCl₃), thionyl chloride (SOCl₂), chlorine (Cl₂), boron tribromide (BBr₃), hydrogen (H₂), oxygen (O₂), phosphorus trichloride (PCl₃), methane (CH₄), methanol (CH₃OH), ammonia (NH₃), formic acid (CH₂O₂), nitrogen trichloride (NF₃), and/or hydrogen fluoride (HF).

FIGS. 1A and 1B illustrate that the surface treatment unit 70 is included in the transport 50, but aspects are not limited thereto. For example, at least a part of the surface treatment unit 70 may be included in the index unit 10, or may be disposed in various positions such as between the index unit 10 and the spin unit 20, between the index unit 10 and the bake unit 30, etc.

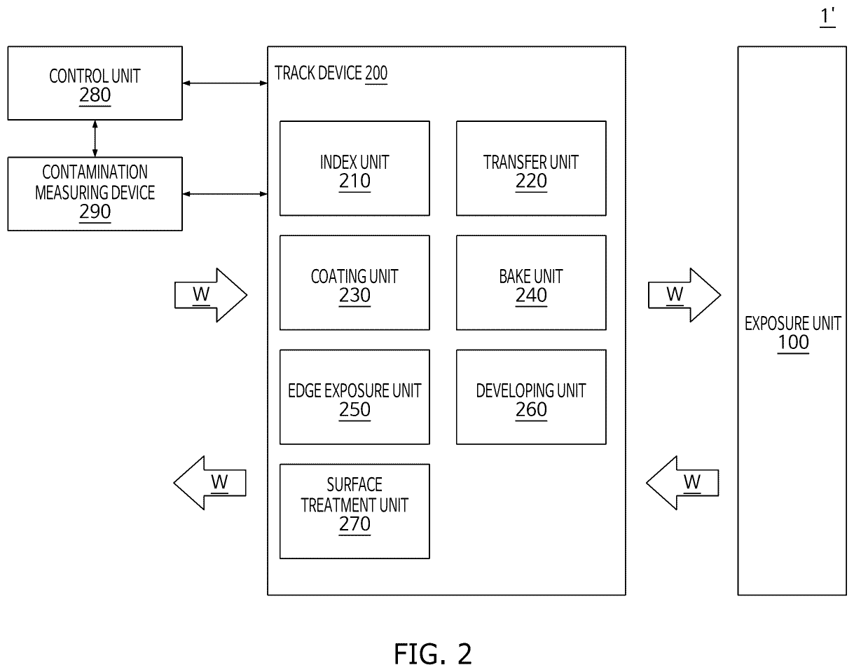

FIG. 2 is a block diagram schematically illustrating a detailed configuration of a substrate processing system 1′. The substrate processing system 1′may include a track device 200 that forms a photoresist film and forms a photoresist pattern from the photoresist film, and an exposure unit 100 that forms a photoresist pattern area by radiating light onto the photoresist film. The substrate processing system 1′ of FIG. 2 may correspond to at least a part of the substrate processing system 1 of FIGS. 1A and 1B, and redundant description thereof is omitted for brevity.

The exposure unit 100 of FIG. 2 may correspond to the exposure unit 60 of FIGS. 1A and 1B, and redundant description thereof is omitted for brevity. The exposure unit 100 may radiate light onto the photoresist film formed on one surface of the substrate W to form a photoresist pattern area. The photoresist pattern area may be an area where the photosensitive reaction occurs upon radiation of light onto the photoresist film. The exposure unit 100 may receive the substrate W from the track device 200, perform the exposure process, and transfer the substrate W to the track device 200.

In some example embodiments, the track device 200 may form a photoresist film on the substrate W such as a semiconductor wafer. The track device 200 may form a photoresist pattern from the photoresist film provided on the substrate W. For example, the substrate W may include a silicon wafer including features having irregular surface topography formed on an upper surface of the substrate W.

The track device 200 may include an index unit 210, a transfer unit 220, a coating unit 230, a bake unit 240, an edge exposure unit 250, a developing unit 260, and a surface treatment unit 270. The index unit 210, the transfer unit 220, the coating unit 230, the bake unit 240, the developing unit 260, and the surface treatment unit 270 of FIG. 2 may correspond to the index unit 10, the transfer unit 40, the coating unit 21, the bake unit 30, the developing unit 22, and the surface treatment unit 70 of FIGS. 1A and 1B, respectively, and redundant description thereof is omitted for brevity.

The transfer unit 220 may include a load station that receives the substrate W, a substrate transfer system that moves the substrate W within the track device 200, and a transfer station that transfers the substrate W. The transfer unit 220 may move the substrate W between the index unit 210, the coating unit 230, the bake unit 240, the edge exposure unit 250, the developing unit 260, and the surface treatment unit 270.

The edge exposure unit 250 may perform a wide exposure edge (WEE) process of exposing an unnecessary photosensitive solution applied to an edge portion of the substrate W, and an alignment process of preliminarily aligning the position and direction of the substrate W having the exposed edge portion.

Operations of the track device 200 and the respective components in the track device 200 may be controlled through a control unit 280. Although FIG. 2 illustrates that the control unit 280 is disposed outside the track device 200, the control unit 280 may be positioned inside the track device 200. The control unit 280 may include one or more processors for controlling the track device 200, a memory that stores a program code, and a communication station for transmitting and receiving information to and from each component in the track device 200, etc.

A control unit or controller may be a computer or several interconnected computers, and may include, for example, one or more processors configured by software, such as a central processing unit (CPU) configured to execute computer program instructions to perform various processes and methods, graphics processor (GPU), random access memory (RAM) and read only memory (ROM) configured to access and store data and information and computer program instructions, input/output (I/O) devices configured to provide input and/or output to the processing controller (e.g., keyboard, mouse, display, speakers, printers, modems, network cards, etc.), and storage media or other suitable type of memory (e.g., such as, for example, RAM, ROM, programmable read-only memory (PROM), erasable programmable read-only memory (EPROM), electrically erasable programmable read-only memory (EEPROM), magnetic disks, optical disks, floppy disks, hard disks, removable cartridges, flash drives, any type of tangible and non-transitory storage medium) where data and/or instructions can be stored. In addition, the controller can include antennas, network interfaces that provide wireless and/or wire line digital and/or analog interface to one or more networks over one or more network connections.

The substrate processing system 1′ may include a contamination measuring device 290 that measures the contamination level of one or both surfaces of the substrate W input to the track device 200.

The contamination measuring device 290 may measure the presence or absence of contamination, type of contamination, contamination level, etc. for one or both surfaces of the substrate W. For example, the contamination measuring device 290 may detect particle contamination with dust or fine particles present on the surface of the substrate W, organic contamination with compounds such as photoresists or residues present on the surface of the substrate W, inorganic contamination with non-organic residues such as metal ions or oxides present on the surface of the substrate W, etc.

The contamination measuring device 290 may detect and measure contamination of the surface of the substrate W using various inspection methods. For example, the contamination measuring device 290 may detect and measure the contamination of the surface of the substrate W using: an optical inspection method that detects particles or defects on the surface using optical-based sensors such as lasers or field microscopes; a scanning electron microscope (SEM) for high-resolution imaging; an atomic force microscopy (AFM) that measures the roughness and topography of the surface to detect particle or chemical contamination; ellipsometry for measuring the thickness and uniformity of thin films to detect chemical contamination; an X-ray photoelectron spectroscopy (XPS) for analyzing the chemical components of the surface to identify organic and inorganic pollutants, etc.

The contamination measuring device 290 may calculate the contamination level of the substrate W using various measures. The contamination measuring device 290 may count the number of particles on the surface of the substrate W and calculate a higher contamination level as the number of particles increases or as the size of the particles increases.

The contamination measuring device 290 may measure the roughness of the surface of the substrate W and calculate a higher contamination level as the roughness increases.

The contamination measuring device 290 may use defect density analysis that maps the defect density of the substrate W through optical and SEM-based inspection and calculate a higher contamination level as the defect density increases.

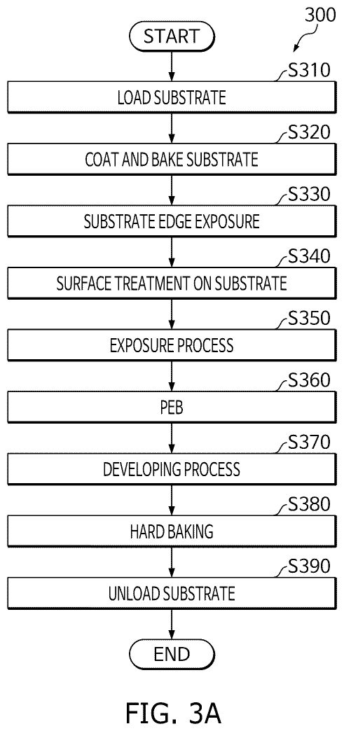

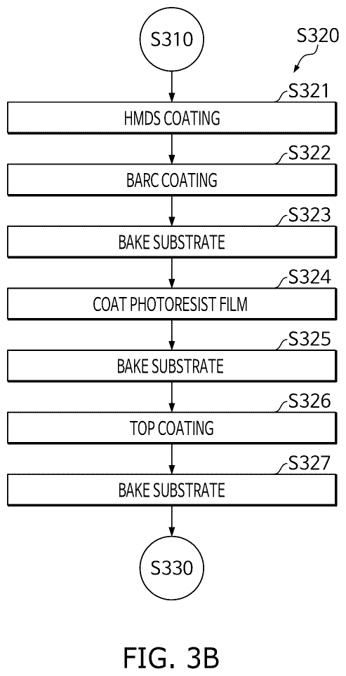

FIG. 3A is a flowchart provided to explain a substrate processing method 300, and FIG. 3B is a flowchart provided to explain the operation S320 in FIG. 3A in detail. The substrate processing method 300 may be performed using the substrate processing system 1′ of FIG. 2.

Referring to FIGS. 2 and 3A, the index unit 210 may load the substrate W onto the track device 200, at S310.

The coating unit 230 and the bake unit 240 may coat and bake the loaded substrate W, at S320. In one example, the coating unit 230 may apply a photoresist film to one surface of the substrate W, and the bake unit 240 may heat the substrate W to heat the photoresist film applied onto the substrate W. The substrate W may be moved between the coating unit 230 and the bake unit 240 by the transfer unit 220.

Referring to FIGS. 3A and 3B, the operation S320 of FIG. 3A may include operations S321 to S327.

In detail, the coating unit 230 may perform hydrophobization of one surface of the substrate W. For example, the coating unit 230 may coat one surface of the substrate W with HMDS, at S321.

After the hydrophobization of one surface of the substrate W is performed and before the photoresist film is applied, the coating unit 230 may coat anti-reflective coating on one surface of the substrate W. The anti-reflective coating may be applied on the HMDS coated at S321. For example, the coating unit 230 may apply bottom anti-reflective coating (BARC), at S322. The bake unit 240 may bake the anti-reflective coated substrate W, at S323.

The coating unit 230 may coat a photoresist film on one surface of the substrate W, at S324. The photoresist film may be coated on the anti-reflective coating applied at S322. The bake unit 240 may bake the substrate W coated with the photoresist film, at S325.

The coating unit 230 may apply top coating on one surface of the substrate W, at S326. The top coating may be applied on the photoresist film coated at S324. The bake unit 240 may bake the substrate W on which the top coating is applied, at S327.

The edge exposure unit 250 may perform an edge exposure process of exposing an unnecessary photoresist applied to the edge portion of the substrate W, at S330. The position and direction of the substrate W having the exposed edge portion may be aligned.

The surface treatment unit 270 may perform a surface treatment on one surface of the substrate W, at S340. The one surface of the substrate W subjected to the surface treatment may be a surface opposite to the surface to which the photoresist is applied. The substrate W after the surface treatment may be transferred to the exposure unit 100.

The exposure unit 100 may perform an exposure process on the substrate W that is surface-treated on one surface, at S350. For example, the exposure unit 100 may radiate light onto the photoresist film formed on the substrate W to form a photoresist pattern area. The substrate W subjected to the exposure process may be transferred back to the track device 200.

The bake unit 240 may perform a post exposure bake (PEB) process of heating the substrate W including the photoresist pattern area formed by the exposure unit 100, at S360.

The developing unit 260 may perform a developing process on the substrate W after the exposure process, at S370. The developing unit 260 may remove an area (e.g., an unnecessary area) different from the photoresist pattern area from the photoresist film on the substrate W to form a photoresist pattern. For example, the developing unit 260 may remove partial areas from the substrate W (e.g., the PEB-processed substrate W) heated by the bake unit 240 to form a photoresist pattern.

The bake unit 240 may hard bake the substrate W including the photoresist pattern formed by the developing unit 260, at S380.

The index unit 210 may unload the hard-baked substrate W from the track device 200, at S390.

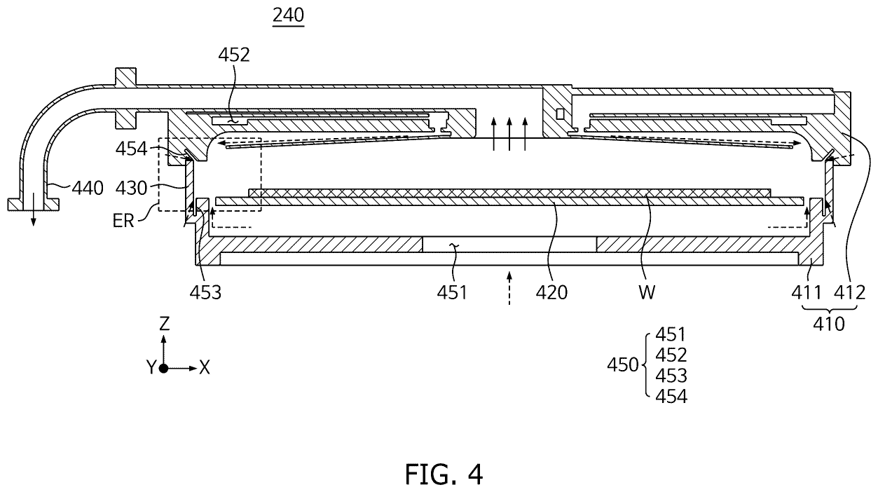

FIG. 4 is a diagram illustrating a detailed configuration of the bake unit 240.

The bake unit 240 may include a process chamber 410, a bake plate 420, a ring shutter 430, a discharge unit 440, and a plurality of inlet units 450.

The process chamber 410 may include a lower chamber 411 and an upper chamber 412, and the photoresist film or the photoresist pattern of the substrate W may be heated in the chamber. The ring shutter 430 may connect the lower chamber 411 and the upper chamber 412 to separate the interior of the process chamber 410 from the outside, and may protect the substrate W through a vertical motion. The plurality of inlet units 450 may include first to fourth inlet units 451, 452, 453, and 454. Fumes and metal particles generated in the process chamber 410 may be discharged to the discharge unit 440 by gas injected through the first inlet unit 451 and the second inlet unit 452. An external gas may be introduced through the third inlet unit 453 and the fourth inlet unit 454, and may form an airflow.

The substrate W may be positioned on the bake plate 420 and heated, and in this process, the solvent of the photoresist may be removed from the surface opposite to the surface in contact with the bake plate 420, or the photoresist film or photoresist pattern may be heated.

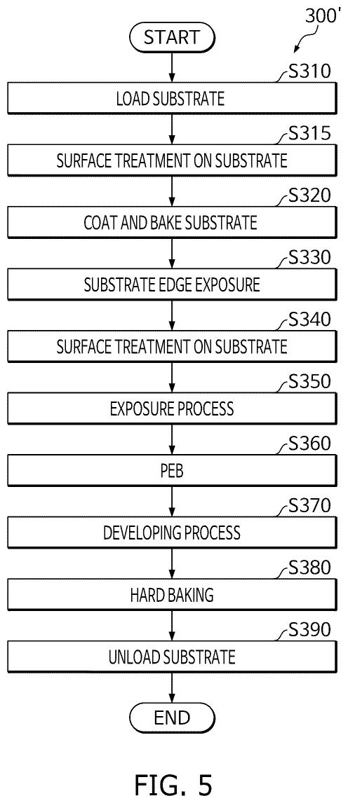

Since the substrate W is positioned on the bake plate 420 and heated, if contamination is present on one surface of the substrate W in contact with the bake plate 420, an area in which contamination is present is not easily heated compared to other areas, and thus the substrate W may be unevenly heated. If there is contamination (e.g., particles) on one surface of the substrate W in contact with the bake plate 420, there is a concern that the bake plate 420 may be contaminated and may cross-contaminate other substrates. This problem may occur in the same way in the coating unit (e.g., 230 in FIG. 2). A modification of the substrate processing method 300 of FIG. 3A for solving this problem will be described below with reference to FIG. 5.

FIG. 5 is a flowchart provided to explain a substrate processing method 300′ according to another aspect of the present disclosure. The substrate processing method 300′ may be performed using the substrate processing system 1′ of FIG. 2, and may be a modification of the substrate processing method 300 illustrated and described above with reference to FIG. 3A. Description overlapping the substrate processing method 300 described above with reference to FIG. 3A will be omitted for brevity.

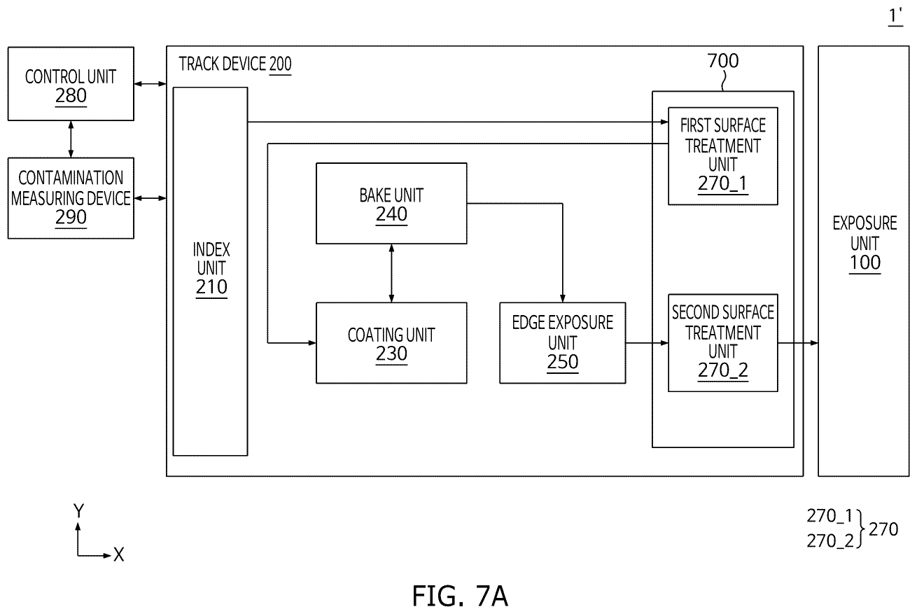

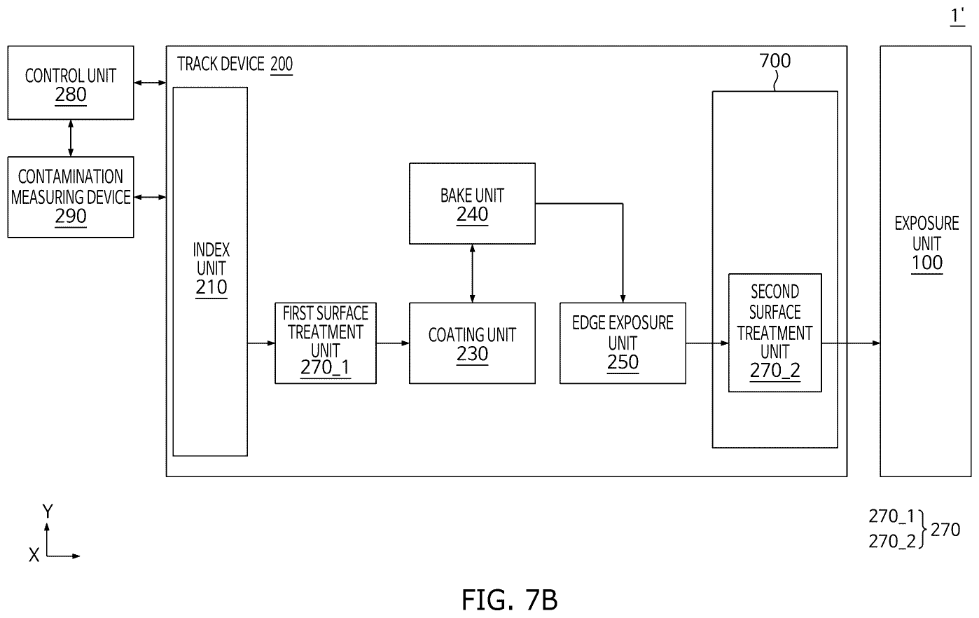

Referring to FIGS. 2 and 5, and compared to the substrate processing method 300 of FIG. 3A, the substrate processing method 300′ of FIG. 5 may further involve performing a first surface treatment on the substrate W before the operation S320, by using the surface treatment unit 270, at S315 (first surface treatment). The first and second surface treatments on the substrate W performed at each of S315 and S340, respectively, may be performed on the first surface of the substrate W, and the substrate coating and baking performed at S320 may be performed on the second surface which is opposite to the first surface of the substrate. The surface treatment unit 270 may include a first surface treatment unit that performs the first surface treatment of S315, and a second surface treatment unit that performs the second surface treatment of S340. This will be described in detail below with reference to FIGS. 7A and 7B.

The first surface treatment on the first surface of the substrate W may be performed by the surface treatment unit 270 before the coating unit 230 applies the photoresist film to the second surface of the substrate W (i.e., before S324 of FIG. 3B).

Before the coating unit 230 applies an anti-reflective coating on the second surface of the substrate W (i.e., before S322 of FIG. 3B), the surface treatment on the first surface of the substrate W may be performed by the surface treatment unit 270.

Before the coating unit 230 performs the hydrophobization on the second surface of the substrate W (i.e., before S321 of FIG. 3B), the first surface treatment on the first surface of the substrate W may be performed by the surface treatment unit 270.

Accordingly, it is possible to prevent the problem of uneven heating of the substrate W due to contamination of the surface of the substrate W when heating the substrate W in the bake unit 240. It is possible to prevent the cross-contamination of the other substrates through the coating unit 230 and the bake unit 240 due to contamination of the surface of the substrate W.

Before the exposure unit 100 radiates light onto the photoresist film formed on the substrate W (or before the substrate W is introduced into the exposure unit 100), the second surface treatment on the first surface of the substrate W may be further performed by the surface treatment unit 270, at S340.

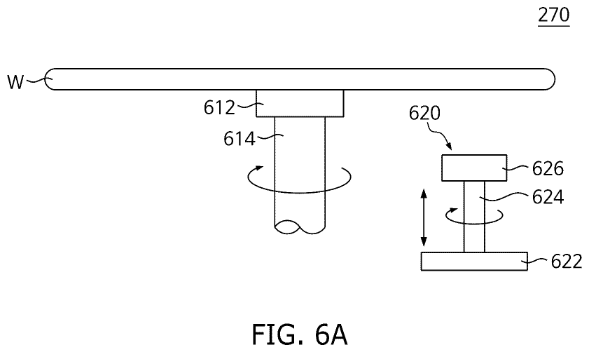

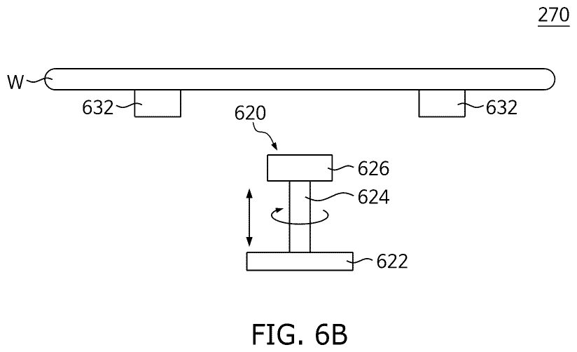

FIGS. 6A and 6B are diagrams illustrating an example in which the surface treatments on the substrate W are performed by the surface treatment unit 270. The surface treatment processes described with reference to FIGS. 6A and 6B may be performed at S315 (first surface treatment) and S340 (second surface treatment) of FIG. 5, respectively, but this is only an example, and alternatively, various types of surface treatment processes may be performed.

Referring to FIG. 6A, the surface treatment unit 270 may include a spin chuck 612 supporting the substrate W, and a rotation unit 614 connected to a lower portion of the spin chuck 612 to transmit a rotational force generated by a driving unit (e.g., a motor, etc.) to the spin chuck 612. The substrate W supported by the spin chuck 612 may be fixed on the spin chuck 612 by electrostatic force or vacuum, and may be rotated according to the rotation of the spin chuck 612. The spin chuck 612 may have a size (e.g., diameter) smaller than that of the substrate W.

The surface treatment unit 270 may include a brush 626 for treating one surface of the substrate W, a spindle 624 connected to the brush 626 to drive the same, and a driving unit 622 providing driving force to the spindle 624.

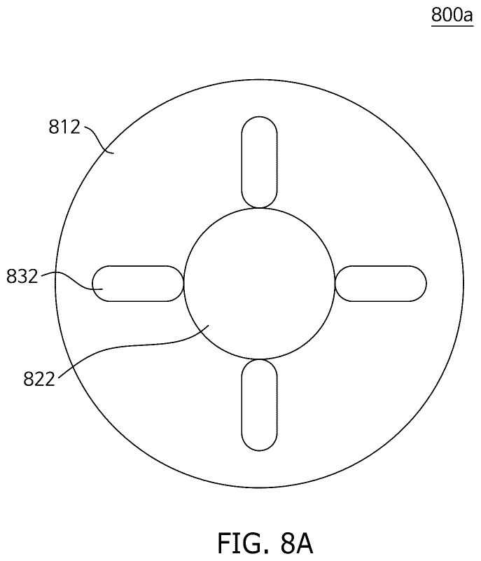

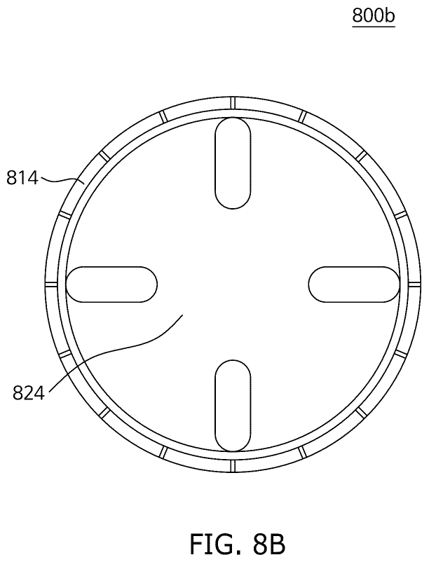

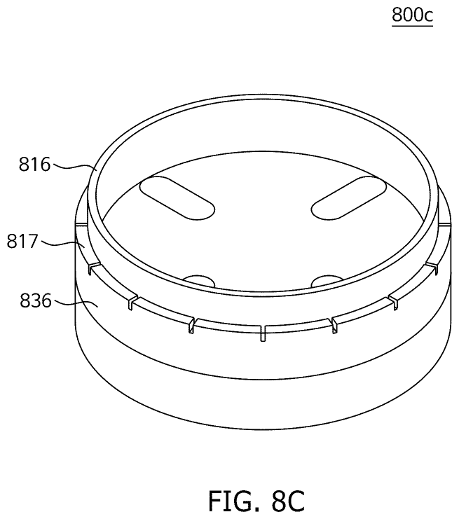

The brush 626 may be configured with various materials and structures. The surface treatment unit 270 may include a plurality of different types of brushes. Various examples of the brush 626 will be described in detail below with reference to FIGS. 8A to 8C.

While the spin chuck 612 is rotated, the brush 626 may be moved and rotated in contact with one surface of the substrate W such that a surface of an area of the one surface of the substrate W except for the area in contact with the spin chuck 612 may be treated.

Referring to FIG. 6B, the spin chuck 612 may be separated from the substrate W in FIG. 6A, and the substrate W may be fixed by a plurality of support members 632. At this time, by moving and rotating the brush 626 in contact with the one surface of the substrate W, the surface (e.g., of a central portion of the one surface) of the substrate W except for the area in contact with the support member 632 may be treated.

FIG. 7A is a block diagram provided to explain an arrangement between units in the track device 200 according to some example embodiments, and FIG. 7B is a block diagram provided to explain an arrangement between units in the track device 200 according to other aspects. The arrows illustrated in the track device 200 of FIGS. 7A and 7B indicate the path of movement of the substrate during the processing of the substrate according to the substrate processing method 300′of FIG. 5. The positions of the units in the track device 200 illustrated in the drawings may reflect the actual relative positions of the units. FIGS. 7A and 7B are provided to schematically illustrate examples of track devices 200 for convenience of explanation, and the distance between blocks and the sizes of blocks do not necessarily reflect the distances between actual units and the sizes of actual units in proportion. Illustrations of some components of the track device 200 have been omitted for brevity.

The track device 200 may include a transport 700 disposed between the coating unit 230 and/or the bake unit 240 and the exposure unit 100, and the transport 700 may correspond to the transport 50 of FIG. 1.

The surface treatment unit 270 may include a first surface treatment unit 270_1 that performs the first surface treatment of S315 of FIG. 5 and a second surface treatment unit 270_2 that performs the second surface treatment of S340 of FIG. 5.

The second surface treatment unit 270_2 may be disposed in the transport 700. The substrate treated by the second surface treatment unit 270_2 may be transferred to the exposure unit 100 through the transport 700.

Referring to FIG. 7A, the first surface treatment unit 270_1 may be disposed in the transport 700. Accordingly, it is not necessary to additionally change the structure of the substrate processing system 1′ to further perform the surface treatment at S315 of FIG. 5.

Referring to FIG. 7B, the first surface treatment unit 270_1 may be disposed to be closer to the index unit 210 than to the second surface treatment unit 270_2. For example, the first surface treatment unit 270_1 may be disposed between the coating unit 230 and the index unit 210. Additionally or alternatively, the first surface treatment unit 270_1 may be disposed between the bake unit 240 and the index unit 210. The substrate treated by the first surface treatment unit 270_1 may be transferred to the coating unit 230. Accordingly, it is possible to solve the problem of inefficiently lengthened movement path of the substrate due to the additional surface treatment of S315 of FIG. 5, thereby providing efficient movement path of the substrate.

Referring to FIGS. 7A and 7B, the first surface treatment unit 270_1 and the second surface treatment unit 270_2 may be controlled by the control unit 280. For example, the control unit 280 may control the surface treatment operation of the surface treatment unit 270 based on the contamination level of one surface of the substrate (e.g., one surface of the substrate to be treated using the surface treatment unit 270) measured using the contamination measuring device 290 before the substrate is input to the substrate processing system 1′.

The surface treatment unit 270 may include a plurality of brushes different from or identical to each other. The plurality of brushes may be the same as or different from each other in material, structure, size, etc.

In response to determining by the contamination measuring device 290 that the contamination level of one surface of the substrate to be treated by the surface treatment unit 270 is greater than or equal to a predetermined threshold level of contamination, the control unit 280 may control the first surface treatment unit 270_1 and the second surface treatment unit 270_2 to perform the first and second surface treatments using different brushes. For example, the control unit 280 may control the surface treatment unit 270 to remove contamination using a brush with relatively better cleaning power in the first surface treatment unit 270_1, and to remove contamination using a brush with relatively low cleaning power in the second surface treatment unit 270_2.

Different brushes may be used by the first surface treatment unit 270_1 between when the contamination level of one surface of the substrate to be treated by the surface treatment unit 270 is determined to be greater than or equal to the predetermined threshold by the contamination measuring device 290, and when it is determined to be less than the predetermined threshold level of contamination. For example, if the contamination measuring device 290 determines that the contamination level of one surface of the substrate is greater than or equal to the threshold, the control unit 280 may control the surface treatment unit 270 to remove contamination using a brush with relatively better cleaning power in the first surface treatment unit 270_1. For example, the one surface of the substrate may be polished and cleaned by using a brush with relatively better cleaning power, such as a brush including a polishing brush and a cleaning brush. An example of the brush including the polishing brush and the cleaning brush will be described below with reference to FIG. 8C.

If it is determined that the contamination level of the one surface of the substrate to be treated by the surface treatment unit 270 is greater than or equal to the predetermined threshold of contamination, the time for the surface treatment may be longer than when the contamination level of the one surface of the substrate to be treated by the surface treatment unit 270 is determined to be less than the threshold. For example, if it is determined that the contamination level is greater than or equal to the threshold, the first surface treatment unit 270_1 may perform the first surface treatment for a first period of time, and if it is determined that the contamination level is less than the threshold, the first surface treatment unit 270_1 may perform the first surface treatment for a second period of time that is shorter than the first period of time. Alternatively, as the contamination level of the one surface of the substrate to be treated by the surface treatment unit 270 increases, the time for the first surface treatment to be performed by the first surface treatment unit 270_1 may increase in proportion.

Likewise, if it is determined that the contamination level is greater than or equal to the predetermined threshold of contamination, the second surface treatment unit 270_2 may perform the second surface treatment for a third period of time, and if it is determined that the contamination level is less than the threshold, the second surface treatment unit 270_2 may perform the second surface treatment for a fourth period of time that is shorter than the third period of time. Alternatively, as the contamination level of the one surface of the substrate to be treated by the surface treatment unit 270 increases, the time for the second surface treatment to be performed by the second surface treatment unit 270_2 may increase in proportion.

FIGS. 8A to 8C are diagrams illustrating examples of brushes 800a, 800b, and 800c according to some example embodiments. The brushes 800a, 800b, and 800c may correspond to the brush 626 of FIGS. 6A and 6B. Main bodies 822, 824, and 836 of the brushes 800a, 800b, and 800c may be fixed to the spindle 624 of FIGS. 6A and 6B, and the brushing units 812, 814, 816, and 817 of the brushes 800a, 800b, and 800c may be fixed to the main bodies 822, 824, and 836.

Referring to FIG. 8A, the brush 800a includes the brushing unit 812 and the body 822, and a groove 832 for increasing the cleaning power of the brush 800a may be formed in the brushing unit 812.

Referring to FIG. 8B, the brushing unit 814 of the brush 800b may be disposed along an outer circumference of the main body 824.

Referring to FIG. 8C, the brushing units 816 and 817 of the brush 800c may include a polishing unit 816 (or referred to as a “polishing brush”) and a cleaning unit 817 (or referred to as a “cleaning brush”). The surface treatment unit may polish and clean one surface of the substrate using the polishing unit 816 and the cleaning unit 817 of the brush 800c. If it is determined that the contamination level of one surface of the substrate to be treated is greater than or equal to a threshold, the brush 800c of FIG. 8C may be used to treat that surface.

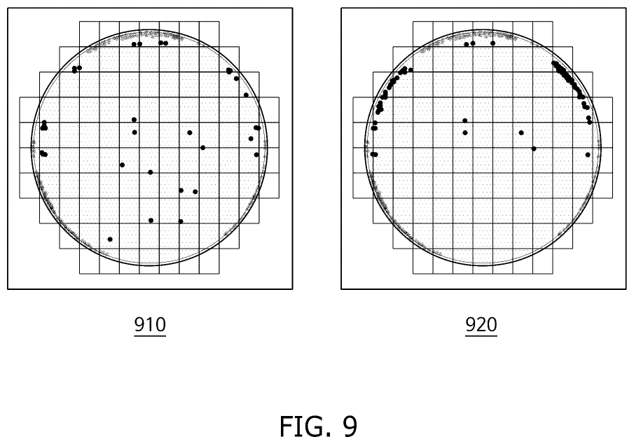

FIG. 9 is a diagram provided to compare the levels of particle contamination on the substrate between when the first surface treatment of the first surface treatment unit 270_1 of FIGS. 7A and 7B is performed and when there is no surface treatment. A first image 910 represents the particle contamination level of the substrate not subjected to the first surface treatment by the first surface treatment unit 270_1 of FIGS. 7A and 7B, and a second image 920 represents the particle contamination level of the substrate subjected to the first surface treatment by the first surface treatment unit 270_1.

As a result of analyzing the second image 920 in comparison with the first image 910, when the first surface treatment by the first surface treatment unit 270_1 is performed, the number of particle contamination with a diameter greater than 5 nm and less than 135 nm is decreased by about 20% from 1,468 to 1,190. Through this, contamination of the coating unit and the bake unit due to particle contamination, etc. may be reduced, and cross-contamination of the other substrates due to the contamination of the coating unit and the bake unit may be reduced.

One or more of the elements and processes disclosed above may include, be implemented in, or be controlled based on processing circuitry such as hardware including logic circuits; a hardware/software combination such as a processor executing software; or a combination thereof. For example, the processing circuitry may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, an application-specific integrated circuit (ASIC), etc. A computer system may be used to control the various processes, which may be automated based for example, on an operator's input, etc., as discussed herein with respect to a controller or control unit.

The present invention is not limited to the aspects described above and the accompanying drawings, and various forms of substitution, modification, and change will be possible by those of ordinary skill in the art without departing from the technical idea of the present disclosure described in the claims, which also fall within the scope of the present disclosure.

1. A substrate processing method, comprising:
performing a first surface treatment on a first surface of a substrate;
subsequently applying a photoresist film on a second surface of the substrate;
subsequently performing a second surface treatment on the first surface of the substrate;
after performing the second surface treatment, radiating light towards the photoresist film to form a photoresist pattern area; and
forming a photoresist pattern by removing from the photoresist film, an area of the photoresist film other than the photoresist pattern area to form the photoresist pattern.

2. The substrate processing method according to claim 1, further comprising applying an anti-reflective coating on the second surface of the substrate, wherein the anti-reflective coating is applied before applying the photoresist film, and after performing the first surface treatment on the first surface of the substrate.

3. The substrate processing method according to claim 1, further comprising performing a hydrophobization of the second surface of the substrate after performing the first surface treatment and before applying the photoresist film on the second surface of the substrate.

4. The substrate processing method according to claim 3, further comprising:
after performing the hydrophobization and before applying the photoresist film, coating an anti-reflective coating on the second surface; and
coating a top coating on an upper portion of the applied photoresist film.

5. The substrate processing method according to claim 1, further comprising:
heating the substrate formed with the photoresist pattern area; and
hard baking the substrate formed with the photoresist pattern, wherein
the photoresist pattern is formed after heating the substrate formed with the photoresist pattern area.

6. The substrate processing method according to claim 1, further comprising transferring the substrate before radiating light towards the photoresist film to form a photoresist pattern area.

7. The substrate processing method according to claim 1, further comprising measuring a contamination level of the first surface of the substrate before inputting the substrate into a substrate processing system.

8. The substrate processing method according to claim 1, wherein performing the first surface treatment and performing the second surface treatment are based on a measured contamination level of the first surface of the substrate, which contamination level is measured before inputting the substrate into a substrate processing system.

9. The substrate processing method according to claim 8, wherein
in response to determining that the contamination level of the first surface of the substrate is greater than or equal to a predetermined threshold, performing the first surface treatment using a first brush and performing the second surface treatment using a second brush,
wherein the first brush comprises a material different from a material of the second brush.

10. The substrate processing method according to claim 8, wherein
when it is determined that the contamination level of the first surface of the substrate is greater than or equal to a predetermined threshold, performing the first surface treatment using a first brush, and
when it is determined that the contamination level of the first surface of the substrate is less than the predetermined threshold, performing the first surface treatment using a second brush.

11. The substrate processing method according to claim 10, wherein performing the first surface treatment comprises polishing and cleaning the first surface of the substrate using a polishing brush and a cleaning brush, in response to determining that the contamination level of the first surface is greater than or equal to the predetermined threshold.

12. The substrate processing method according to claim 8, comprising
when it is determined that the contamination level of the first surface of the substrate is greater than or equal to a predetermined threshold, performing the first surface treatment for a first period of time, and
when it is determined that the contamination level of the first surface of the substrate is less than the predetermined threshold, performing the first surface treatment for a second period of time,
wherein the first period of time is longer than the second period of time.

13. The substrate processing method according to claim 1, further comprising
heating the substrate comprising the photoresist pattern area formed by radiating light toward the photoresist film to form a photoresist pattern area.

14. The substrate processing method according to claim 13, wherein forming the photoresist pattern comprises removing from the photoresist film an area of the photoresist film other than the photoresist pattern area from the heated substrate.

15. The substrate processing method according to claim 14, comprising hard baking the substrate comprising the photoresist pattern.

16. A substrate processing method, comprising:
performing, by a surface treatment chamber, a first surface treatment on a first surface of a substrate;
subsequently applying, by a coating station, a photoresist film on a second surface of the substrate;
subsequently performing, by the surface treatment chamber, a second surface treatment on the first surface of the substrate;
transferring by a transport, the substrate applied with a photoresist film to an exposure station in which a photoresist pattern is formed on the substrate by light radiated toward the photoresist film and transferring the substrate comprising a photoresist pattern area that is formed by light radiated toward the photoresist film, wherein the exposure station is part of a system in which each step herein is performed; and
forming, by a developing chamber, a photoresist pattern by removing from the photoresist film in an area of the photoresist film other than the photoresist pattern area to form the photoresist pattern.

17. A substrate processing system, comprising:
a surface treatment chamber for performing a surface treatment on a first surface of a substrate;
a coating station for applying a photoresist film onto a second surface of the substrate;
an exposure station for radiating light towards the photoresist film to form a photoresist pattern area on the photoresist film;
a developing station for removing from the photoresist film an area other than the photoresist pattern area to form a photoresist pattern, and
a controller configured to cause each step herein to be performed, wherein
the surface treatment chamber performs a first surface treatment on the first surface of the substrate, before the coating station applies the photoresist film onto the second surface of the substrate, and
the surface treatment chamber performs a second surface treatment on the first surface of the substrate, before the exposure station radiates the light towards the photoresist film.

18. The substrate processing system according to claim 17, further comprising a transport disposed between the coating station and the exposure station,
wherein the surface treatment chamber comprises:
a first surface treatment chamber that performs the first surface treatment; and
a second surface treatment chamber that performs the second surface treatment, and
wherein the second surface treatment chamber is disposed in the transport.

19. The substrate processing system according to claim 18, further comprising an index station for transferring a substrate, wherein the first surface treatment chamber is disposed to be closer to the index station than to the second surface treatment chamber.

20. The substrate processing system according to claim 18, wherein the first surface treatment chamber is disposed in the transport.
